(19) United States
(12) Patent Application Publication
(10) Pub. No.: US 2019/0140014 A1
(43) Pub. Date: May 9, 2019

(54) IMAGING DEVICE AND CAMERA SYSTEM

(71) Applicant: Panasonic Intellectual Property Management Co., Ltd., Osaka (JP)

(72) Inventor: TATSUNORI MOMOSE, Osaka (JP)

(21) Appl. No.: 16/168,706

(22) Filed: Oct. 23, 2018

(30) Foreign Application Priority Data
Nov. 9, 2017 (JP) 2017-216105

(51) Int. Cl. H01L 27/146; H04N 5/378

(52) U.S. Cl. CPC H01L 27/14645; H01L 27/14627; H04N 5/378; H01L 27/14623; H01L 27/14641; H01L 27/14603

(57) ABSTRACT

An imaging device includes a first pixel and a second pixel, each of the first pixel and the second pixel including a photoelectric converter that includes a first electrode, a second electrode, and a photoelectric conversion layer between the first electrode and the second electrode and that converts incident light into charge, an amplifier transistor that has a gate electrode coupled to the first electrode and that outputs a signal corresponding to an amount of the charge, and a light attenuator that is layered on the photoelectric conversion layer and that attenuates light toward the photoelectric conversion layer. A transmittance of the light attenuator of the first pixel is different from a transmittance of the light attenuator of the second pixel.

### BACKGROUND

### 1. Technical Field

The present disclosure relates to a stacked type imaging device and a camera system.

### 2. Description of the Related Art

Imaging devices have been widely used in digital still cameras, digital video cameras, and so forth. As imaging devices, for example, amplification type imaging devices and charge transfer type imaging devices have been known. The amplification type imaging device, for example, includes an image sensor of a MOS type such as a complementary metal oxide semiconductor (CMOS). The charge transfer type imaging device, for example, includes a charge coupled device (CCD) image sensor.

In an image sensor, photosensitivity is considered to be important in view of image quality. As the photosensitivity becomes higher, higher signal amplification may be obtained even by a slight incident light amount. Thus, it becomes possible to acquire a high quality image with a high S/N ratio. Various kinds of devising are performed for increasing the photosensitivity. For example, the photosensitivity may be increased by raising the conversion efficiency of a photoelectric conversion unit that converts light into an electric signal.

For example, an organic film stacked type imaging device is present in which an organic thin film with high photoelectric conversion characteristics is arranged as a photoelectric conversion film above a silicon substrate (for example, Japanese Unexamined Patent Application Publication No. 2011-181595). Photosensitivity may be improved by using such a photoelectric conversion film.

### SUMMARY

It is desirable to enhance light resistance of a photoelectric conversion unit in an imaging device.

In one general aspect, the techniques disclosed here feature the following imaging device.

An imaging device according to one aspect of the present disclosure includes a first pixel and a second pixel, each of the first pixel and the second pixel including a photoelectric converter that includes a first electrode, a second electrode, and a photoelectric conversion layer between the first electrode and the second electrode and that converts incident light into charge, an amplifier transistor that has a gate electrode coupled to the first electrode and that outputs a signal corresponding to an amount of the charge, and a light attenuator that is layered on the photoelectric conversion layer and that attenuates light toward the photoelectric conversion layer. A transmittance of the light attenuator of the first pixel is different from a transmittance of the light attenuator of the second pixel.

A general or specific aspect may be embodied by an element, device, module, system, integrated circuit, or method. Further, a general or specific aspect may be embodied by any combination of an element, device, module, system, integrated circuit, and method.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is an outline cross-sectional diagram of a typical organic film stacked type imaging device;

FIG. 2 is an outline cross-sectional diagram of an imaging device according to an embodiment;

FIG. 3 is a diagram that explains differences in the burn-in degree in a case where the light-shielding degree of a light attenuator is changed in the embodiment;

FIG. 4 is a diagram that explains an installation state of the imaging device according to the embodiment;

FIG. 5 is one example of an image in a case where an outside is photographed by the imaging device illustrated in FIG. 4;

FIG. 6 is a diagram of an image-capturing region of the imaging device according to the embodiment as seen in the vertical direction to a surface of a semiconductor substrate;

FIG. 7 is a diagram that explains an elevation angle of the sun in a case where the imaging device according to the embodiment is installed such that a light reception surface is at 90° with respect to a horizontal plane;

FIG. 8 is a graph that represents the relationship between the elevation angle of the sun and the irradiance of sunlight on the light reception surface of the imaging device illustrated in FIG. 7;

FIG. 9 is a diagram that explains the change in the light-shielding degree in a Y axis direction of the image-capturing region;

FIG. 10 is a diagram of the image-capturing region of the imaging device according to the embodiment as seen in the vertical direction to the surface of the semiconductor substrate;

FIG. 11 is a flowchart that illustrates a method for deciding an arrangement position of the light attenuator in the imaging device according to the embodiment;

FIG. 12A is a configuration diagram of a camera system according to the embodiment; and

FIG. 12B is a configuration diagram of a camera system according to a modification example of the embodiment.

### DETAILED DESCRIPTION

### (Underlying Knowledge Forming Basis of the Present Disclosure)

A typical MOS type image sensor uses a photodiode as a photoelectric conversion unit. Such a MOS type image sensor includes a photodiode that is arranged in a silicon substrate and a logic circuit portion that processes an electric signal converted by the photodiode to make image data. In order to enhance the photosensitivity, it is requested to increase the ratio of the area occupied by the photodiode to the area of the whole image sensor. However, because the logic circuit portion may not be removed, there is a limitation on increasing the area of the photodiode. Thus, a method has been suggested in which the photoelectric conversion unit is separated from the silicon substrate and is thereby arranged above the silicon substrate. In a case where the photoelectric conversion unit is arranged above the silicon substrate, the area of the photoelectric conversion unit may be increased. Thus, the photosensitivity may be enhanced. For example, an organic film stacked type imaging device is present in which an organic thin film with high photoelectric conversion characteristics is arranged above a silicon substrate (for example, Japanese Unexamined Patent Application Publication No. 2011-181595). Such a configuration may improve the photosensitivity.

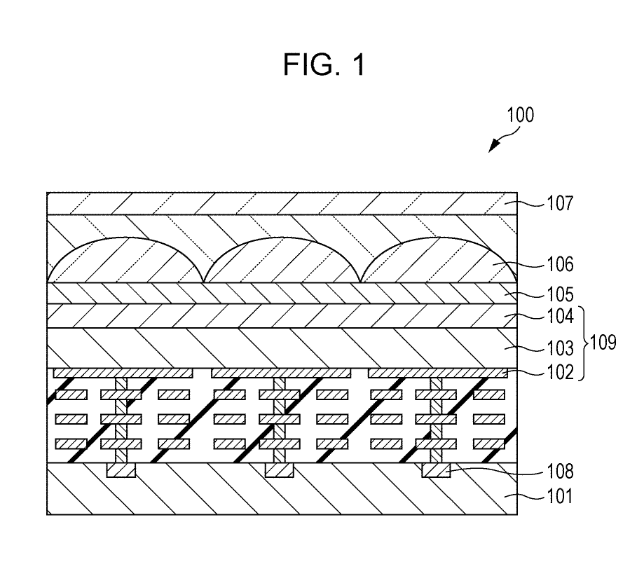

FIG. 1 is an outline cross-sectional diagram of a typical organic film stacked type imaging device 100. As illustrated in FIG. 1, in the typical organic film stacked type imaging device 100, a photoelectric conversion unit 109 is arranged above a semiconductor substrate 101. The semiconductor substrate 101 is a silicon substrate, for example. The photoelectric conversion unit 109 includes a pixel electrode 102, a photoelectric conversion film 103 arranged on the pixel electrode 102, and a transparent electrode 104 arranged on the photoelectric conversion film 103. A color filter 105 is arranged on the transparent electrode 104, and a microlens 106 for condensing light is arranged on the color filter 105. In addition, cover glass 107 for protecting an element is arranged on the microlens 106.

As described above, in order to enhance the photosensitivity, a structure is useful in which the photoelectric conversion unit is arranged above the silicon substrate (Japanese Unexamined Patent Application Publication No. 2011-181595). However, in a case of a stacked type imaging device that uses an organic thin film as a photoelectric conversion film, enhancing the light resistance in the photoelectric conversion unit is demanded. For example, in a case where strong light such as sunlight is condensed by a lens and is incident on the photoelectric conversion unit, the photoelectric conversion film possibly receives irreversible damage. For example, the photosensitivity of the photoelectric conversion film may lower due to a chemical change of a material of the photoelectric conversion film. In a case where the damage is severer, a phenomenon in which the material of the photoelectric conversion film in the portion to which the strong light is condensed is chemically changed and photoelectric conversion may thereby not be performed, that is, a burn-in phenomenon occurs, and lowering in the image quality may be caused.

Such damage to the photoelectric conversion unit may occur in an imaging device in related art in which the photoelectric conversion unit is arranged in the silicon substrate like a photodiode, for example. However, in the imaging device that uses the organic thin film as the photoelectric conversion film, it is considered that damage particularly by sunlight to the photoelectric conversion unit may become large depending on the material of the photoelectric conversion film.

In consideration of above problems about light resistance, it is desirable to provide an imaging device, a method for deciding an arrangement position of a light attenuator in an imaging device, and a camera system that maintain photosensitivity and has high light-resistance.

An outline of one aspect of the present disclosure is as follows.

### [Item 1]

An imaging device including a first pixel and a second pixel, each of the first pixel and the second pixel including a photoelectric converter that includes a first electrode, a second electrode, and a photoelectric conversion layer between the first electrode and the second electrode and that converts incident light into charge, an amplifier transistor that has a gate electrode coupled to the first electrode and that outputs a signal corresponding to an amount of the charge, and a light attenuator that is layered on the photoelectric conversion layer and that attenuates light toward the photoelectric conversion layer. A transmittance of the light attenuator of the first pixel is different from a transmittance of the light attenuator of the second pixel.

### [Item 2]

The imaging device according to Item 1, in which the second electrode functions as the light attenuator, and a transmittance of the second electrode of the first pixel is different from a transmittance of the second electrode of the second pixel.

### [Item 3]

The imaging device according to Item 1 or 2, in which each of the first pixel and the second pixel includes a color filter that is located on the second electrode and that functions as the light attenuator, a color of the color filter of the first pixel is the same as a color of the color filter of the second pixel, and a transmittance of the color filter of the first pixel is different from a transmittance of the color filter of the second pixel.

### [Item 4]

The imaging device according to any one of Items 1 to 3, in which each of the first pixel and the second pixel includes a microlens that is located on the second electrode and that functions as the light attenuator, and a transmittance of the microlens of the first pixel is different from a transmittance of the microlens of the second pixel.

### [Item 5]

The imaging device according to any one of Items 1 to 4, in which each of the first pixel and the second pixel includes a cover glass located on the second electrode and that functions as the light attenuator, and a transmittance of the cover glass of the first pixel is different from a transmittance of the cover glass of the second pixel.

### [Item 6]

The imaging device according to any one of Items 1 to 5, in which each of the first pixel and the second pixel includes a color filter that is located on the second electrode, and an insulating layer that is located between the second electrode and the color filter and that functions as the light attenuator, and a transmittance of the insulating layer of the first pixel is different from a transmittance of the insulating layer of the second pixel.

### [Item 7]

The imaging device according to any one of Items 1 to 6, in which each of the first pixel and the second pixel includes a color filter located on the second electrode, a microlens located on the color filter, and an insulating layer that is located between the color filter and the microlens and that functions as the light attenuator, and a transmittance of the insulating layer of the first pixel is different from a transmittance of the insulating layer of the second pixel.

### [Item 8]

The imaging device according to any one of Items 1 to 7, in which each of the first pixel and the second pixel includes a microlens that is located on the color filter, a cover glass located on the microlens, an insulating layer that is located between the microlens and the cover glass and that functions as the light attenuator, and a transmittance of the insulating layer of the first pixel is different from a transmittance of the insulating layer of the second pixel.

### [Item 9]

The imaging device according to any one of Items 1 to 8, in which the photoelectric conversion layer includes an organic material.

### [Item 10]

The imaging device according to any one of Items 1 to 9, wherein a material constituting the light attenuator of the first pixel is different from a material constituting the light attenuator of the second pixel.

### [Item 11]

The imaging device according to any one of Items 1 to 10, wherein the light attenuator is indirectly on the photoelectric conversion layer.

### [Item 12]

A camera system including: a lens optical system; the imaging device according to any one of Items 1 to 11 that receives light passing through the lens optical system and that outputs a signal; and a signal processing circuit that processes the signal.

Further, an outline of one aspect of the present disclosure is as follows.

An imaging device according to one aspect of the present disclosure includes a semiconductor substrate, a pixel unit that includes plural pixels, and a light attenuator that attenuates light which is incident on the pixel unit. Each of the plural pixels includes a photoelectric conversion unit that is located above the semiconductor substrate and that converts incident light into charge and a charge detection circuit that detects the charge. The photoelectric conversion unit has a photoelectric conversion film that includes an organic material.

In such a manner, the light attenuator is provided which attenuates light which is incident on the pixel unit, and the light amount that is incident on the photoelectric conversion unit may thereby be decreased. Thus, the photoelectric conversion film may be inhibited from being damaged by strong light. Accordingly, light resistance of the imaging device may be improved.

For example, in the imaging device according to one aspect of the present disclosure, the light attenuator may cover a portion of the pixel unit.

Accordingly, the light attenuator may be arranged only in a portion in the pixel unit on which strong light is incident, for example. In such a manner, only the portion in the pixel unit on which strong light is incident is covered by the light attenuator. Thus, while the photoelectric conversion film is inhibited from being damaged by strong light, photoelectric conversion may efficiently be performed for the light that is incident on the pixel unit.

For example, in the imaging device according to one aspect of the present disclosure, the light attenuator may have a first region that has a first transmittance and a second region that has a second transmittance which is lower than the first transmittance, and the second region may cover one portion of the pixel unit.

Accordingly, the second region with a lower transmittance than the first region may be arranged in a portion on which stronger light is incident.

For example, in the imaging device according to one aspect of the present disclosure, the one portion of the pixel unit may be a region on which more light is incident than a region other than the one portion of the pixel unit.

In such a manner, the light attenuator is arranged in a portion in which the incident light amount is large, and optical damage to the photoelectric conversion film may thereby be decreased.

For example, in the imaging device according to one aspect of the present disclosure, the one portion of the pixel unit may be an upper region of the pixel unit when seen in the vertical direction to the semiconductor substrate.

In such a manner, the one portion of the pixel unit is the upper region of the pixel unit when seen in the vertical direction to a surface of the semiconductor substrate. Thus, for example, in a case where photographing is performed outdoors by using the imaging device, sunlight is likely to be incident on the upper region of the pixel unit. Consequently, the light attenuator is arranged in a region on which strong light is likely to be incident, and the optical damage to the photoelectric conversion film may thereby be decreased.

For example, in the imaging device according to one aspect of the present disclosure, the second region may have a third region whose light-shielding ratio gradually lowers from an upper end portion toward a lower end portion when seen in the vertical direction to the semiconductor substrate.

For example, in a case where photographing is performed outdoors by using the imaging device, the incident light amount of sunlight is reduced from an upper end portion toward a lower end portion. Thus, the second region of the light attenuator has the third region whose light-shielding ratio gradually changes, and the light-shielding ratio may thereby be adjusted in accordance with the incident light amount of sunlight. Consequently, in the third region, the light amount that is incident on the pixel unit may be made uniform.

For example, in the imaging device according to one aspect of the present disclosure, the light attenuator may be located above a borderline that crosses the pixel unit in the left-right direction when seen in the vertical direction to the semiconductor substrate, and the borderline may be in the position on the pixel unit that corresponds to the horizon in an image captured outside by using the imaging device.

In such a manner, in a plan view of the pixel unit, the borderline that crosses the pixel unit in the left-right direction is in the position on the pixel unit that corresponds to the horizon in an image captured, and the light attenuator may thereby be arranged in the region on which sunlight is likely to be incident in a case where the light attenuator is arranged above the borderline of the pixel unit. Thus, the optical damage to the photoelectric conversion film may be decreased.

For example, in the imaging device according to one aspect of the present disclosure, the position of the borderline may be decided depending on a mounting angle at which the imaging device is mounted with respect to a horizontal plane and an angle of view in the perpendicular direction that is a viewing angle in a case where the imaging device photographs an outside.

In such a manner, because the position of the borderline is decided in accordance with the installation state of the imaging device, the arrangement position of the light attenuator may be decided in response to the installation state of the imaging device.

For example, in the imaging device according to one aspect of the present disclosure, the position of the borderline may be decided by calculation by using formula (1) given that the vertical width of the region of the one portion with respect to the vertical width of the pixel unit is set as a, the vertical width of the region other than the one portion is set as b, the mounting angle is set as ϕ, and the angle of view is set as θ when seen in the vertical direction to the semiconductor substrate.

$$\frac{b}{a + b} = 1 - \frac{( \frac{θ}{2} + ϕ - 90 )}{θ} \qquad ( 1 )$$

Accordingly, the arrangement position of the light attenuator may be decided more finely in response to the installation state of the imaging device.

Further, a method for deciding the arrangement position of the light attenuator in the imaging device according to one aspect of the present disclosure is a method for deciding an arrangement position of the light attenuator in the imaging device that includes the pixel unit which includes the plural pixels and the light attenuator that attenuates light which is incident on the pixel unit. The method includes a step of deciding the position of the horizon on the pixel unit in a case where an outside view is captured by the imaging device and a step of arranging the light attenuator above the borderline that corresponds to the position of the horizon image when seen in the vertical direction to the semiconductor substrate and that crosses the pixel unit in the left-right direction.

In such a manner, in a plan view of the pixel unit, the borderline that crosses the pixel unit in the left-right direction is in the position that corresponds to the horizon image on the pixel unit, and the light attenuator may thereby be arranged in the region on which sunlight is likely to be incident in a case where the light attenuator is arranged above the borderline on the pixel unit. Thus, the optical damage to the photoelectric conversion film may be decreased.

For example, in the method for deciding the arrangement position of the light attenuator in the imaging device according to one aspect of the present disclosure, in the step of deciding the position of the horizon, the position of the horizon may be decided based on the mounting angle at which the imaging device is mounted with respect to the horizontal plane and the angle of view in the perpendicular direction in a case where the imaging device photographs an outside.

Accordingly, the arrangement position of the light attenuator may be decided in response to the installation state of the imaging device.

For example, in the method for deciding the arrangement position of the light attenuator in the imaging device according to one aspect of the present disclosure, the position of the borderline may be decided by calculation by using formula (1) given that the vertical width of the region of the one portion with respect to the vertical width of the pixel unit is set as a, the vertical width of the region other than the one portion is set as b, the mounting angle is set as ϕ, and the angle of view is set as θ when seen in the vertical direction to the semiconductor substrate.

$$\frac{b}{a + b} = 1 - \frac{( \frac{θ}{2} + ϕ - 90 )}{θ} \qquad ( 1 )$$

Accordingly, the arrangement position of the light attenuator may be decided more finely in response to the installation state of the imaging device.

Further, a camera system according to one aspect of the present disclosure includes the imaging device that includes the semiconductor substrate, the photoelectric conversion unit which is positioned above the semiconductor substrate and converts incident light into charge, and the charge detection circuit which detects the charge, and the light attenuator that attenuates light which is incident on the imaging device. The photoelectric conversion unit has the photoelectric conversion film that includes an organic material.

The camera system has such a configuration and may thereby attenuate light that is incident on the imaging device. Thus, the photoelectric conversion film may be inhibited from being damaged by strong light.

An embodiment of the present disclosure will hereinafter be described in detail with reference to drawings.

Note that the embodiment described in the following illustrates general or specific examples. Values, shapes, materials, configuration elements, arrangement positions or connection manners of configuration elements, steps, orders of steps, and so forth that are described in the following embodiment are merely illustrative and are not intended to limit the present disclosure. Further, the configuration elements that are not described in the independent claims which provide the most superordinate concepts among the configuration elements in the following embodiment will be described as arbitrary configuration elements. In the diagrams, the same reference characters are given to substantially the same configurations, and repeated descriptions may not be made or may be simplified.

Further, various elements illustrated in the drawings are only schematically illustrated for understanding of the present disclosure, and dimension ratios, external appearances, and so forth may be different from actual articles.

Note that herein, a light reception side of an imaging device is defined as “above”, and the opposite side to the light reception side is defined as “below”. As for “upper surface” and “lower surface” of each member, similarly, a surface that is opposed to the light reception side of the imaging device is defined as “upper surface”, and a surface that is opposed to the opposite side to the light reception side is defined as “lower surface”. Herein, the terms “above”, “below”, “upper surface”, and “lower surface” are used to only designate relative arrangement of members and are not intended to limit the position of the imaging device in use.

### (Embodiment)

In the following, a description will be made about an imaging device, a method for deciding an arrangement position of a light attenuator in an imaging device, and a camera system according to this embodiment.

### [Imaging Device]

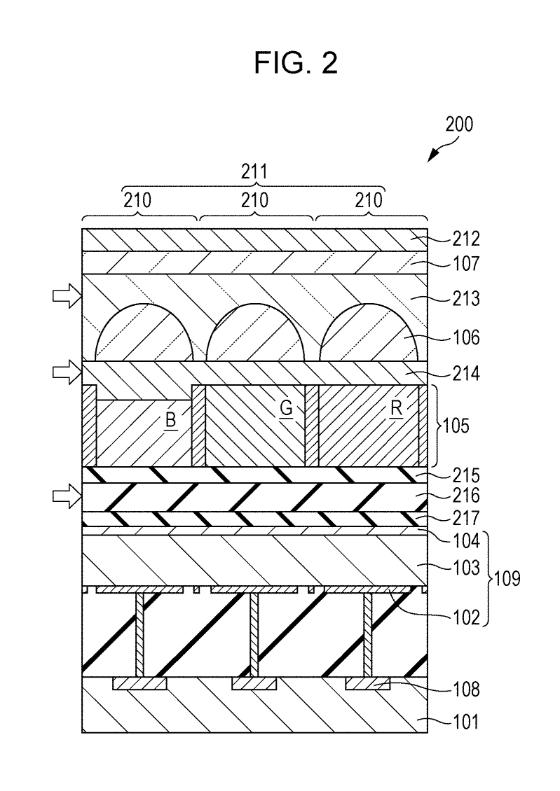

First, a description will be made about a configuration of the imaging device according to this embodiment. FIG. 2 is an outline cross-sectional diagram of an imaging device 200 according to the embodiment.

The imaging device 200 according to this embodiment includes a semiconductor substrate 101, a pixel unit 211 that includes plural pixels 210, and a light attenuator 212 that attenuates light which is incident on the pixel unit 211.

Each of the plural pixels 210 is positioned on the semiconductor substrate 101 and includes a photoelectric conversion unit 109 that converts incident light into charge and a charge detection circuit 108 that detects charge.

The photoelectric conversion unit 109 has a pixel electrode 102, a photoelectric conversion film 103 that is arranged on the pixel electrode 102, and a transparent electrode 104 that is arranged on the photoelectric conversion film 103.

Further, a color filter 105 is arranged on the transparent electrode 104, a flattening film 214 is arranged on the color filter 105, and a microlens 106 is arranged on the flattening film 214. In addition, cover glass 107 is arranged on the microlens 106, and the light attenuator 212 is arranged on the cover glass 107.

In this embodiment, the light attenuator 212 is arranged on the cover glass 107 that is an uppermost surface of the imaging device 200. Note that the light attenuator 212 is provided to lessen optical damage to the photoelectric conversion film 103. That is, it is sufficient that the light attenuator 212 is arranged on the photoelectric conversion film 103, and embodiments are not limited to the arrangement position of the light attenuator 212 in this embodiment. Further, it is sufficient that the light attenuator 212 may attenuate incident light, that is, reduce the light intensity of the incident light. The light attenuator 212 may be a light-shielding film or may be a light-shielding material that is combined with each configuration of the imaging device, for example. The light-shielding film may be a neutral density (ND) filter, a chromic film, or a liquid crystal film, for example.

The arrows in FIG. 2 indicate positions where the light attenuator 212 may be arranged. In a case where the light attenuator 212 is the light-shielding film, the light attenuator 212 may be arranged between the cover glass 107 and the microlens 106. For example, the light attenuator 212 may be arranged upon or beneath a transparent resin layer 213. Further, the light attenuator 212 may be arranged between the microlens 106 and the color filter 105. For example, the light attenuator 212 may be arranged upon or beneath the flattening film 214. Further, the light attenuator 212 may be arranged between the color filter 105 and the transparent electrode 104. For example, the light attenuator 212 may be arranged between any of insulating films 215, 216, and 217.

Note that in a case where the light-shielding material is included in each element of the imaging device 200, the light-shielding material may be included in at least one of the cover glass 107, the transparent resin layer 213, the microlens 106, the flattening film 214, the color filter 105, the insulating film 215, the insulating film 216, the insulating film 217, and the transparent electrode 104, which are arranged on the photoelectric conversion film 103. The light-shielding material may be a light-absorbing material such as chromium or indium, for example. The light-shielding material may be carbon black, acetylene black, coal tar, or a black pigment precursor, for example. For example, in a case where the light-shielding material is included in the transparent electrode 104, indium may be combined as the light-shielding material. In a case where the indium amount is increased in order to enhance the light-shielding degree, the electrical conductivity of the transparent electrode 104 is enhanced. In a case where the transparent resin layer 213, the microlens 106, the flattening film 214, the color filter 105, the insulating film 215, the insulating film 216, and the insulating film 217 are formed of a resin, carbon black may be included in those as the light-shielding material. When the transparent resin layer 213, the microlens 106, the flattening film 214, the color filter 105, the insulating film 215, the insulating film 216, the insulating film 217, and the transparent electrode 104 are formed, for example, a content ratio of the light-shielding material in each element or a thickness of each element may be changed stepwise by using a mask. Accordingly, regions with mutually different transmittances may be formed. In a case where the light-shielding material is included in the cover glass 107, a metal thin film or a dielectric thin film may be formed on a surface of the cover glass 107, and the transmittance may thereby be adjusted. The film thickness of the metal thin film or the dielectric thin film, which is formed on the surface of the cover glass 107, may be changed stepwise, and the regions with mutually different transmittances may thereby be formed.

The pixel electrode 102 is an electrode that is formed of metal, a metal nitride, or polysilicon to which conductivity is added, for example. A metal used for the pixel electrode 102 includes aluminum and copper, for example. As a method for adding conductivity to the polysilicon, for example, doping with impurities may be used. The pixel electrode 102 is spatially separated from the pixel electrodes 102 of other neighboring pixels 210 and is thereby electrically separated from the pixel electrodes 102 of other pixels 210.

The transparent electrode 104 may include a transparent conductive oxide such as indium tin oxide (ITO), indium zinc oxide (IZO), aluminum-doped zinc oxide (AZO), fluorine-doped tin oxide (FTO), SnO₂, TiO₂, or ZnO₂, for example.

The photoelectric conversion film 103 includes an organic material such as quinacridone or tin naphthalocyanine, for example. The photoelectric conversion film 103 may include an inorganic semiconductor material such as amorphous silicon in addition to the organic material. Further, the organic material may include either one or both of an n-type organic semiconductor and a p-type organic semiconductor.

The charge detection circuit 108 detects signal charge that is trapped by the pixel electrode 102 and outputs a signal voltage. The charge detection circuit 108 includes an amplifier transistor, a resent transistor, and an address transistor, for example. The charge detection circuit 108 is formed on the semiconductor substrate 101, for example. The gate of the amplifier transistor is connected to the pixel electrode 102. One of the source and drain of the reset transistor is connected with the pixel electrode 102.

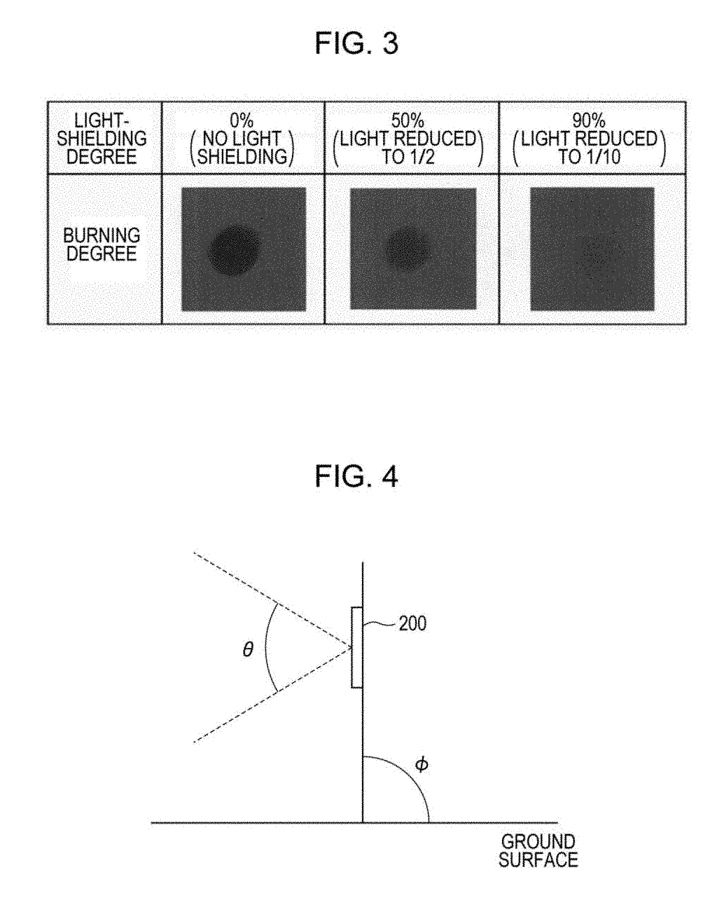

Next, a description will be made about the relationship between the light attenuation ratio by the light attenuator 212 and the burn-in degree of the pixel unit 211. Here, the light attenuator 212 is the ND filter, for example. FIG. 3 is a diagram that explains differences in the obtained image in a case where the light-shielding degree of the light attenuator 212 is changed in the embodiment.

As illustrated in FIG. 3, in a case where light shielding was not performed by the ND filter, that is, in a case of the light-shielding degree 0%, a black spot was generated in a portion of the image. Further, in a case where the incident light amount on the photoelectric conversion film was reduced to ½ by using the ND filter, that is, in a case of the light-shielding degree 50%, a gray spot was generated in a portion of the image. Further, in a case where the incident light amount on the photoelectric conversion film was reduced to 1/10 by using the ND filter, that is, in a case of the light-shielding degree 90%, a pale spot was generated in a portion of the image. From those results, it was found that in a case where the light-shielding degree of the ND filter was raised to 90%, burn-in to the imaging device was decreased, and the influence by the burn-in to the obtained image became small to the extent that the influence of the burn-in was hardly noticed. In such a manner, the incident light amount on the photoelectric conversion film is reduced by raising the light-shielding degree of the ND filter, the optical damage to the photoelectric conversion film may thereby be decreased, and the degree of the influence of the burn-in on the obtained image may be made small.

In the following, a description will be made about a structure for enhancing the light-shielding performance in a case where the imaging device 200 is used for an in-vehicle camera and a monitoring camera.

FIG. 4 is a diagram that explains an installation state of the imaging device 200 according to the embodiment. An angle θ in FIG. 4 indicates the viewing angle in the perpendicular direction of the imaging device 200, that is, the angle of view in the perpendicular direction. An angle ϕ indicates a mounting angle of the imaging device 200, that is, the angle that is formed between a light reception surface of the imaging device 200 and a horizontal plane. The horizontal plane is a ground surface, for example.

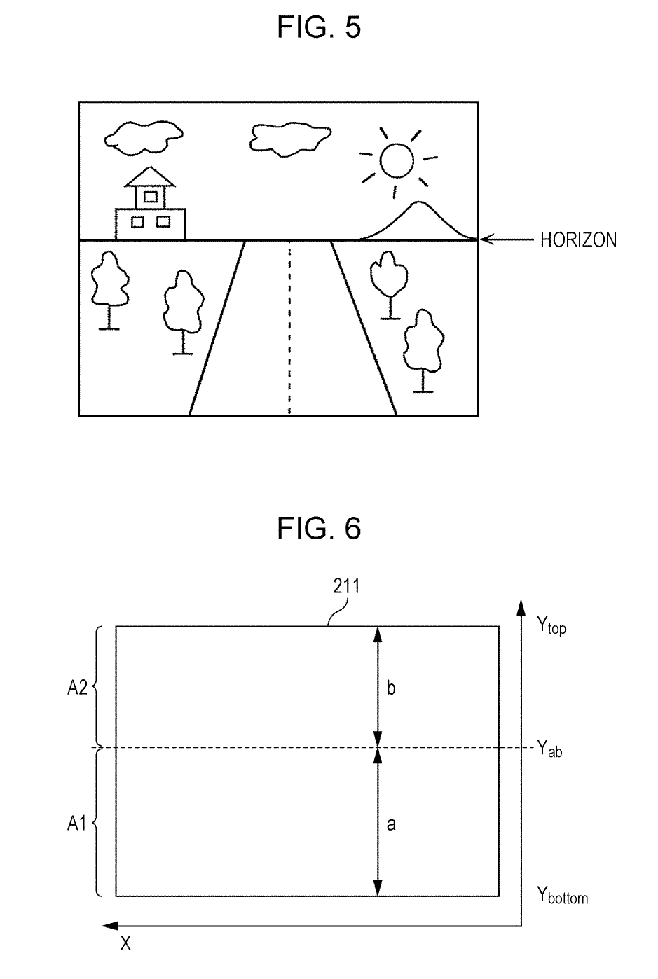

As illustrated in FIG. 4, the imaging device 200 is installed such that the mounting angle becomes ϕ with respect to the horizontal plane. Here, in a case where photographing is performed outdoors by using the imaging device 200, an image of the distant horizon is captured by the pixel unit 211 as illustrated in FIG. 5. FIG. 5 is one example of an image in a case where photographing is performed outdoors by using the imaging device 200 illustrated in FIG. 4. The pixel unit 211 may hereinafter be referred to as image-capturing region 211.

As illustrated in FIG. 5, the distant horizon is displayed in the image photographed by the imaging device 200. The sky is displayed in a region above the horizon. Consequently, sunlight may directly be incident on a portion of the pixel unit 211 that captures an image of the region above the horizon. The photoelectric conversion film 103 that is positioned in such a portion possibly receives an influence of sunlight.

FIG. 6 is a diagram of the image-capturing region 211 of the imaging device 200 according to the embodiment as seen in the vertical direction to a surface of the semiconductor substrate 101. Here, a description will be made about a case where the imaging device 200 is installed such that the light reception surface becomes vertical with respect to the horizontal plane. In FIG. 6, the horizontal direction is represented by an X axis, and the vertical direction is represented by a Y axis. Further, Yₜₒₚ is the uppermost side of the image-capturing region 211, and Y_{bottom} is the lowermost side of the image-capturing region 211. Here, an object image that is formed in the image-capturing region 211 of the imaging device 200 is actually inverted in the up-down and left-right directions by a lens optical system. Consequently, for example, an object image of the sun or the like, which is present above the horizon, appears below the image of the horizon in the image-capturing region 211. However, herein, for easy understanding, a region in which an image of an object positioned above the horizon is formed will be referred to as an upper region of the image-capturing region 211, and a region in which an image of an object positioned below the horizon is formed will be referred to as a lower region of the image-capturing region 211.

As described above with reference to FIG. 5, sunlight may directly be incident on a region A2 of the pixel unit 211 in which an image of an object above the horizon is formed. In a portion of the photoelectric conversion film 103 on which sunlight is directly incident, for example, an irreversible chemical change possibly occurs. In a portion in which an irreversible chemical change occurs, a phenomenon in which photoelectric conversion is not performed even if light is incident occurs, that is, the burn-in phenomenon occurs, and lowering in the image quality is caused.

In order to decrease such an influence, in the imaging device 200, a portion of the pixel unit 211 may be covered by the light attenuator 212 such as a light-shielding film, for example. Here, the portion of the pixel unit 211 is the upper region A2 of the pixel unit 211 when seen in the vertical direction to the surface of the semiconductor substrate 101. As described above with reference to FIG. 5, the region A2 of the pixel unit 211 captures an image of an object above the horizon. Thus, the light attenuator 212 may be positioned above a borderline Y_{ab} that crosses the pixel unit 211 in the left-right direction when seen in the vertical direction to the surface of the semiconductor substrate 101. Note that the borderline Y_{ab} that crosses in the left-right direction is in the position that corresponds to the horizon image on the pixel unit 211 in a case where the imaging device 200 captures an image outdoors.

The position of the borderline Y_{ab} may be decided based on the mounting angle ϕ of the imaging device 200 with respect to the horizontal plane and the angle θ of view in the perpendicular direction of the imaging device 200. Specifically, the position of the borderline Y_{ab} that crosses the pixel unit 211 in the left-right direction may be decided by calculation by using formula (1) given that the vertical width of a region A1 with respect to the vertical width of the pixel unit 211 is set as a, the vertical width of the region A2 is set as b, the mounting angle is set as ϕ, and the angle of view in the perpendicular direction is set as θ when seen in the vertical direction to the surface of the semiconductor substrate 101.

$$\frac{b}{a + b} = 1 - \frac{( \frac{θ}{2} + ϕ - 90 )}{θ} \qquad ( 1 )$$

The region A2 of the pixel unit 211 is a region on which more light is incident than on the region A1 of the pixel unit 211. In this embodiment, the whole pixel unit 211 may be covered by the light attenuator 212. Here, the light attenuator 212 may have a first region that has a first transmittance and a second region that has a second transmittance which is lower than the first transmittance, and the second region may cover the region A2 of the pixel unit 211.

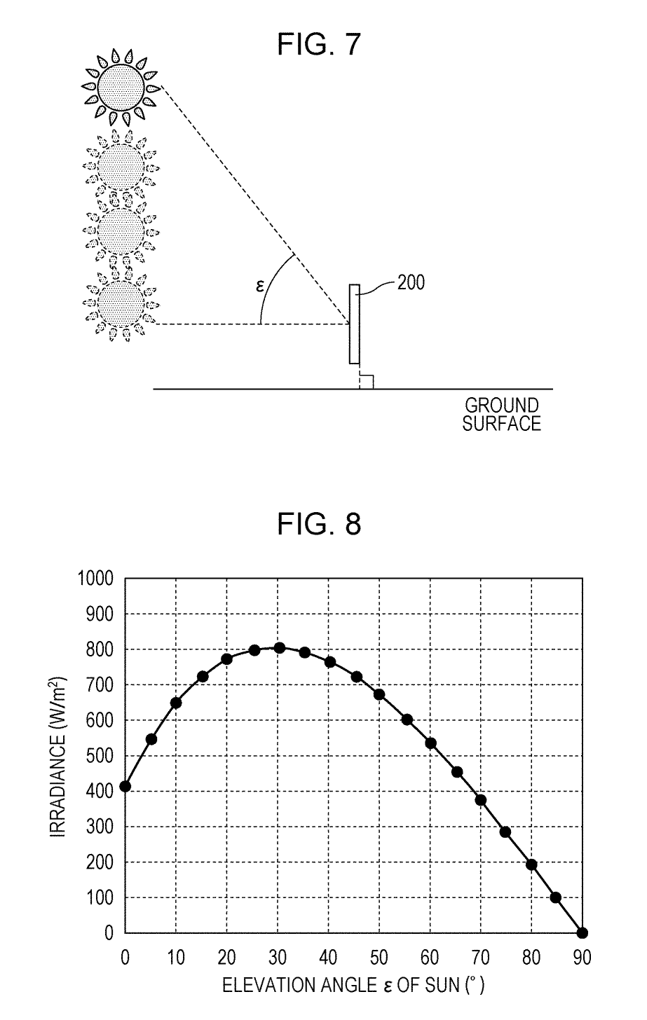

Next, a description will be made about the relationship between the position of the sun as seen from the imaging device 200 and the irradiance of sunlight that is received by the photoelectric conversion film 103. FIG. 7 is a diagram that explains an elevation angle ε of the sun in a case where the imaging device 200 according to the embodiment is installed such that the light reception surface is at 90° with respect to the horizontal plane. In FIG. 7, the horizontal plane is the ground surface. FIG. 8 is a graph that represents the relationship between the elevation angle ε of the sun and the irradiance of sunlight on the light reception surface of the imaging device 200.

As illustrated in FIG. 7, the elevation angle ε of the sun is the angle that is formed between the normal line with respect to the light reception surface of the imaging device 200 and the straight line drawn between the center of the light reception surface of the imaging device 200 and the sun.

As illustrated in FIG. 8, the irradiance of sunlight changes in accordance with the elevation angle ε of the sun. Note that the relationship between the irradiance of sunlight and the elevation angle ε of the sun differs in accordance with the mounting angle ϕ, of the imaging device 200. In a case where the imaging device 200 is installed such that the light reception surface is at 90° with respect to the horizontal plane, as the elevation angle ε of the sun becomes a lower angle, the thickness of the atmospheric layer through which sunlight is transmitted increases, and the light absorption by the atmosphere becomes more. Thus, the irradiance of sunlight becomes the maximum when the elevation angle ε of the sun becomes 30°.

As illustrated in FIG. 8, the irradiance of sunlight changes in accordance with the elevation angle ε of the sun. For example, in a case where the elevation angle ε of the sun is 30°, the sunlight that is condensed to the imaging device 200 through the lens is incident with a high radiant intensity around the uppermost side Yₜₒₚ of the image-capturing region 211 and is incident with a low radiant intensity around the borderline Y_{ab} compared to a portion around the uppermost side Yₜₒₚ. Thus, the light-shielding degree of the region A2 from the borderline Y_{ab} to the uppermost side Yₜₒₚ of the image-capturing region 211 may continuously be changed.

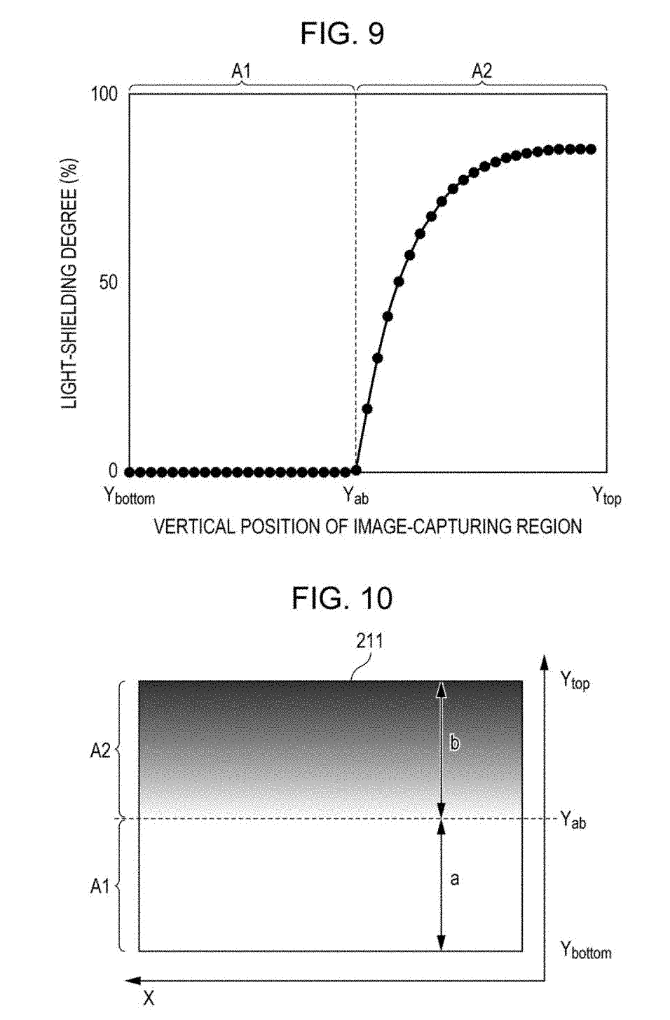

FIG. 9 illustrates an example where in the light attenuator 212, the light-shielding degree in a region corresponding to the region A2 of the image-capturing region 211 is continuously changed in the Y axis direction. As illustrated in FIG. 9, the light that is incident on the image-capturing region 211 from an object below the horizon is condensed, through the lens (which is not illustrated in FIG. 9), to the region A1 that is positioned below the borderline Y_{ab}. The borderline Y_{ab} crosses the pixel unit 211 in the left-right direction. Further, the light that is incident on the image-capturing region 211 from an object above the horizon is condensed, through the lens (which is not illustrated in FIG. 9), to the region A2 that is positioned above the borderline Y_{ab}.

Because sunlight is not directly incident on the region A1, external light that is condensed through the lens is received by the pixel unit 211 without any change. The region A1 does not receive strong light like sunlight and is thus not covered by the light attenuator 212. Accordingly, the light-shielding degree of the region A1 is 0%. Note that the region A1 may be covered by the light attenuator 212. In this case, the light attenuator 212 may have the first region that has the first transmittance and the second region that has the second transmittance which is lower than the first transmittance, and the region A1 may be covered by the first region.

On the other hand, sunlight may directly be incident on the region A2. External light that is condensed through the lens is condensed to a prescribed region of the pixel unit 211 in accordance with the angle of incidence on the lens. For example, in a case where the elevation angle ε of the sun is 30°, the light that is incident on the lens at 30° is condensed around the uppermost side Yₜₒₚ of the image-capturing region 211. In other words, the sun is photographed around the uppermost side Yₜₒₚ of the image-capturing region 211. Meanwhile, as the elevation angle ε of the sun becomes smaller than 30°, that is, as the angle at which sunlight is incident on the lens becomes smaller, light is condensed to a portion closer to the borderline Y_{ab}. That is, as the elevation angle ε of the sun becomes larger from 0° to 30°, the position to which sunlight is condensed moves from the borderline Y_{ab} toward the uppermost side Yₜₒₚ. Further, as the elevation angle ε of the sun becomes larger from 0° to 30°, the radiant intensity of sunlight becomes higher. Thus, the region A2 is covered by the light attenuator 212. Further, here, the light attenuator 212 has the first region that has the first transmittance and the second region that has the second transmittance which is lower than the first transmittance, and the region A2 is covered by the second region.

Note that the region A2 may be covered by the light attenuator 212 having a uniform light-shielding degree or may be covered by the light attenuator 212 having light-shielding degree that is continuously changed. FIG. 10 is a diagram of the image-capturing region 211 of the imaging device 200 as seen in the vertical direction to the surface of the semiconductor substrate 101.

As illustrated in FIG. 10, in the imaging device 200 according to this embodiment, the second region has a third region whose light-shielding ratio gradually lowers from an upper end portion toward a lower end portion when seen in the vertical direction to the surface of the semiconductor substrate 101. In the region A2, as illustrated in FIG. 8, the irradiance and the incident position of sunlight change in accordance with the elevation angle ε of the sun. Thus, in the region A2, the light-shielding degree is changed in response to the irradiance and the incident position of sunlight. For example, because sunlight is incident with a high radiant intensity around the uppermost side Yₜₒₚ of the image-capturing region 211, the light-shielding degree of a portion around the uppermost side Yₜₒₚ is made high. On the other hand, because sunlight is incident around the borderline Y_{ab}, for example, with a low radiant intensity compared to a portion around the uppermost side Yₜₒₚ, the light-shielding degree of a portion around the borderline Y_{ab} is made lower than a portion around the uppermost side Yₜₒₚ. Accordingly, it becomes possible to provide an imaging device that maintains photosensitivity and has high light-resistance.

### [Method For Deciding Arrangement Position of Light Attenuator]

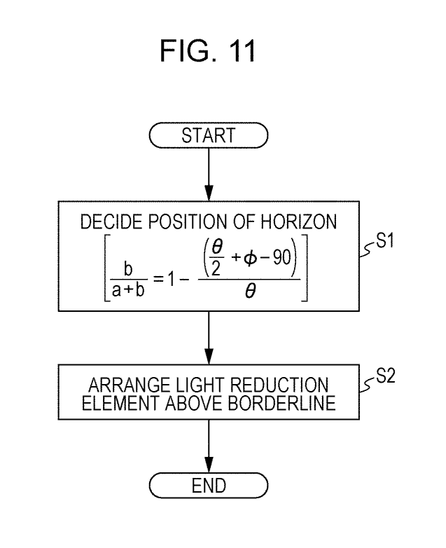

Next, a description will be made about a method for deciding an arrangement position of the light attenuator 212 in the imaging device 200 according to this embodiment. FIG. 11 is a flowchart that illustrates the method for deciding the arrangement position of the light attenuator 212 in the imaging device 200 according to this embodiment.

The method for deciding the arrangement position of the light attenuator 212 in the imaging device 200 according to this embodiment is a method for deciding an arrangement position of the light attenuator 212 in the imaging device 200. The imaging device 200 includes the pixel unit 211 which includes the plural pixels 210 and the light attenuator 212 that attenuates light which is incident on the pixel unit 211. The method includes a step of deciding a position of a horizon image captured by the pixel unit 211 in a case where photographing is performed outdoors by using the imaging device 200 (step S1), and a step of arranging the light attenuator 212 above the borderline Y_{ab} that corresponds to the position of the horizon when seen in the vertical direction to the surface of the semiconductor substrate 101 (step S2). The borderline Y_{ab} crosses the pixel unit 211 in the left-right direction.

More specifically, in the step of deciding the position of the horizon in step S1, the position of the horizon is decided based on the mounting angle ϕ of the imaging device 200 with respect to the horizontal plane and the angle θ of view in the perpendicular direction of the imaging device 200.

More specifically, the position of the borderline Y_{ab}, which corresponds to the position of the horizon and crosses the pixel unit 211 in the left-right direction, is decided by calculation by using formula (1) given that the vertical width of the region above the borderline Y_{ab} in the pixel unit 211 is set as a, the vertical width of the region below the borderline Y_{ab} is set as b, the mounting angle is set as ϕ, and the angle of view is set as θ when seen in the vertical direction to the surface of the semiconductor substrate 101.

$$\frac{b}{a + b} = 1 - \frac{( \frac{θ}{2} + ϕ - 90 )}{θ} \qquad ( 1 )$$

Accordingly, the arrangement position of the light attenuator 212 may be decided more finely in response to the installation state of the imaging device 200.

Note that the method may be conducted by a system controller of a camera system, which will be described later. The system controller may be provided on the outside of the camera system.

### [Camera System]

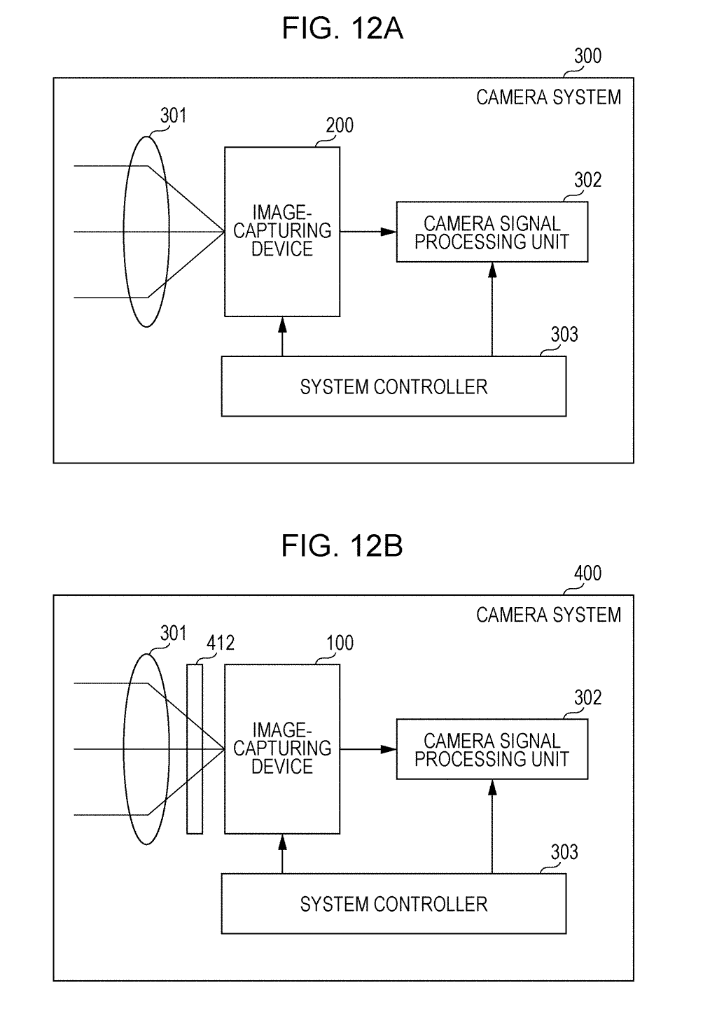

In the following, a description will be made about a camera system according to this embodiment. FIG. 12A is a configuration diagram of a camera system 300 according to this embodiment.

The camera system 300 includes a lens optical system 301, the imaging device 200, a system controller 303, and a camera signal processing unit 302. The lens optical system 301 may include an autofocus lens, a zoom lens, and a diaphragm, for example. The lens optical system 301 condenses light to the light reception surface of the imaging device 200. As the imaging device 200, the above-described imaging device 200 according to the embodiment may widely be used. The system controller 303 controls the whole camera system 300. The system controller 303 may be realized by a microcomputer, for example. The camera signal processing unit 302 functions as a signal processing circuit that processes an output signal from the imaging device 200. The camera signal processing unit 302 performs processes such as gamma correction, a color interpolation process, a space interpolation process, and white balance, for example. The camera signal processing unit 302 may be realized by a digital signal processor (DSP) or the like, for example. In the camera system 300 according to this embodiment, the light resistance of the photoelectric conversion unit may be improved by using the above-described imaging device 200 according to this embodiment. As a result, burn-in in the photoelectric conversion unit may be inhibited, and an image with proper image quality may be acquired.

Next, a description will be made about a camera system according to a modification example of this embodiment. FIG. 12B is a configuration diagram of a camera system 400 according to the modification example of the embodiment. In this modification example, a description will be made about different configurations from the camera system 300 according to the embodiment.

The camera system 400 according to this modification example is different from the camera system 300 in a point that a light attenuator 412 is provided on the outside of the imaging device 100 (see FIG. 1). As described above with reference to FIG. 1, the imaging device 100 does not have the light attenuator 212.

Specifically, the camera system 400 according to this modification example includes the imaging device 100 that includes the semiconductor substrate 101, the photoelectric conversion unit 109 which is located above the semiconductor substrate 101 and converts incident light into charge, and the charge detection circuit 108 which detects the charge and the light attenuator 412 that attenuates light which is incident on the imaging device 100. The photoelectric conversion unit 109 has the photoelectric conversion film 103 that includes an organic material.

The camera system 400 according to this modification example has such a configuration and may thereby attenuate light that is incident on the imaging device 100. Thus, the photoelectric conversion film may be inhibited from being damaged by strong light.

In the foregoing, a description has been made about the imaging device, the method for deciding the arrangement position of the light attenuator in the imaging device, and the camera system according to the present disclosure based on the embodiment. However, the present disclosure is not limited to the embodiment. Modes in which various modifications conceived by persons having ordinary skill in the art are applied to the embodiment and other modes that are constructed by combining a portion of configuration elements in the embodiment may be included in the scope of the present disclosure unless the modes depart from the gist of the present disclosure.

The imaging device according to the present disclosure may be used for cameras such as a digital camera and an in-vehicle camera.

What is claimed is:

1. An imaging device comprising:
a first pixel and a second pixel, each of the first pixel and the second pixel including
a photoelectric converter that includes a first electrode, a second electrode, and a photoelectric conversion layer between the first electrode and the second electrode and that converts incident light into charge,
an amplifier transistor that has a gate electrode coupled to the first electrode and that outputs a signal corresponding to an amount of the charge, and
a light attenuator that is layered on the photoelectric conversion layer and that attenuates light toward the photoelectric conversion layer, wherein
a transmittance of the light attenuator of the first pixel is different from a transmittance of the light attenuator of the second pixel.

2. The imaging device according to claim 1, wherein
the second electrode functions as the light attenuator, and
a transmittance of the second electrode of the first pixel is different from a transmittance of the second electrode of the second pixel.

3. The imaging device according to claim 1, wherein
each of the first pixel and the second pixel includes a color filter that is located on the second electrode and that functions as the light attenuator,
a color of the color filter of the first pixel is the same as a color of the color filter of the second pixel, and
a transmittance of the color filter of the first pixel is different from a transmittance of the color filter of the second pixel.

4. The imaging device according to claim 1, wherein
each of the first pixel and the second pixel includes a microlens that is located on the second electrode and that functions as the light attenuator, and
a transmittance of the microlens of the first pixel is different from a transmittance of the microlens of the second pixel.

5. The imaging device according to claim 1, wherein
each of the first pixel and the second pixel includes a cover glass located on the second electrode and that functions as the light attenuator, and
a transmittance of the cover glass of the first pixel is different from a transmittance of the cover glass of the second pixel.

6. The imaging device according to claim 1, wherein
each of the first pixel and the second pixel includes
a color filter that is located on the second electrode, and
an insulating layer that is located between the second electrode and the color filter and that functions as the light attenuator, and
a transmittance of the insulating layer of the first pixel is different from a transmittance of the insulating layer of the second pixel.

7. The imaging device according to claim 1, wherein
each of the first pixel and the second pixel includes
a color filter located on the second electrode,
a microlens located on the color filter, and
an insulating layer that is located between the color filter and the microlens and that functions as the light attenuator, and
a transmittance of the insulating layer of the first pixel is different from a transmittance of the insulating layer of the second pixel.

8. The imaging device according to claim 1, wherein
each of the first pixel and the second pixel includes
a microlens that is located on the color filter,
a cover glass located on the microlens,
an insulating layer that is located between the microlens and the cover glass and that functions as the light attenuator, and
a transmittance of the insulating layer of the first pixel is different from a transmittance of the insulating layer of the second pixel.

9. The imaging device according to claim 1, wherein the photoelectric conversion layer includes an organic material.

10. The imaging device according to claim 1, wherein a material constituting the light attenuator of the first pixel is different from a material constituting the light attenuator of the second pixel.

11. The imaging device according to claim 1, wherein the light attenuator is indirectly on the photoelectric conversion layer.

12. A camera system comprising:
a lens optical system;
the imaging device according to claim 1 that receives light passing through the lens optical system and that outputs a signal; and
a signal processing circuit that processes the signal.
